(19) United States
(12) Patent Application Publication
(10) Pub. No.: US 2026/0231636 A1
(43) Pub. Date: Aug. 6, 2026

(54) DISPLAY PANEL AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Wenbo CHEN, Beijing (CN); Mengqi WANG, Beijing (CN); Ziyang YU, Beijing (CN); Zhiliang JIANG, Beijing (CN); Fei CHEN, Beijing (CN); Ming HU, Beijing (CN); Haijun QIU, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 19/150,541

(22) PCT Filed: Jul. 10, 2024
(86) PCT No.: PCT/CN2024/104673

§ 371 Date: Jul. 24, 2025

(30) Foreign Application Priority Data
Aug. 3, 2023 (CN) 202310974470.7

(51) Int. Cl. H10K 59/131

(52) U.S. Cl. CPC H10K 59/131

(57) ABSTRACT

Provided is a display panel. The display panel has a display region, and includes: a base substrate; and a plurality of pixel circuits arrayed on a side of the base substrate, wherein the plurality of pixel circuits include a plurality of first pixel circuits and a plurality of dummy pixel circuits; a plurality of light-emitting devices on a side of the plurality of pixel circuits away from the base substrate, wherein the plurality of light-emitting devices are electrically connected to the plurality of first pixel circuits in one-to-one correspondence; and a plurality of data signal lines and a plurality of redundant signal lines that are disposed in the display region, wherein an extension direction of the plurality of data signal lines is coincident with an extension direction of the plurality of redundant signal lines.

### CROSS-REFERENCE TO RELATED APPLICATIONS

This application is a U.S. national stage of international application No. PCT/CN2024/104673, filed on Jul. 10, 2024, which claims priority to Chinese Patent Application No. 202310974470.7, filed on Aug. 3, 2023 and entitled “DISPLAY PANEL AND DISPLAY DEVICE,” the disclosures of each are herein incorporated by references in their entireties.

### TECHNICAL FIELD

The present disclosure relates to the field of display technology, and more particularly to a display panel and a display device.

### BACKGROUND

At present, display screens (also referred to as a display panel) in display devices are becoming large screens and full screens to provide users with greater visual experience.

### SUMMARY

Embodiments of the present disclosure provide a display panel and a display device. The technical solutions are as follows.

In some embodiments of the present disclosure, a display panel is provided. The display panel has a display region, and includes:
a base substrate; and
a plurality of pixel circuits arrayed on a side of the base substrate, wherein the plurality of pixel circuits include a plurality of first pixel circuits and a plurality of dummy pixel circuits;
a plurality of light-emitting devices on a side of the plurality of pixel circuits away from the base substrate, wherein the plurality of light-emitting devices are electrically connected to the plurality of first pixel circuits in one-to-one correspondence; and
a plurality of data signal lines and a plurality of redundant signal lines that are disposed in the display region, wherein an extension direction of the plurality of data signal lines is coincident with an extension direction of the plurality of redundant signal lines;
wherein one of the plurality of data signal lines is electrically connected to one column of the plurality of first pixel circuits, one of the plurality of redundant signal lines is disposed in a region of one column of the plurality of dummy pixel circuits, and at least some of the plurality of redundant signal lines are first redundant signal lines, wherein one of the first redundant signal lines includes a first lead portion connected to one of the plurality of data signal lines.

In some embodiments, the display panel further includes: a plurality of auxiliary signal lines in the display region, wherein an extension direction of the plurality of auxiliary signal lines is intersected with the extension direction of the plurality of redundant signal lines,
one of the plurality of auxiliary signal lines is disposed in a region of one row of the plurality of pixel circuits, and at least some of the plurality of auxiliary signal lines are first auxiliary signal lines, wherein one of the first auxiliary signal lines includes a second lead portion, wherein one end of the second lead portion is electrically connected to one of the plurality of data signal lines, and another end of the second lead portion is electrically connected to an end of the first lead portion.

In some embodiments, one of the first redundant signal lines further includes a redundant line body disconnected from the first lead portion, and one of the first auxiliary signal lines further includes an auxiliary line body disconnected from the second lead portion,
wherein the redundant line body is electrically connected to the auxiliary line body at an intersection between the redundant line body and the auxiliary line body.

In some embodiments, some of the plurality of redundant signal lines are the first redundant signal lines, and some of the plurality of redundant signal lines are second redundant signal lines, wherein the first lead portion is not disposed in the second redundant signal lines, and each of the second redundant signal lines is electrically connected to the auxiliary line body at an intersection between the each of the second redundant signal lines and the auxiliary line body; and/or
some of the plurality of auxiliary signal lines are the first auxiliary signal lines, and some of the plurality of auxiliary signal lines are second auxiliary signal lines, wherein the second lead portion is not disposed in the second auxiliary signal lines, and each of the second auxiliary signal lines is electrically connected to the redundant line body at an intersection between the each of the second auxiliary signal lines and the redundant line body.

In some embodiments, in a case where the display panel includes the second redundant signal lines and the second auxiliary signal lines, each of the second redundant signal lines is electrically connected to one of the second auxiliary signal lines at an intersection between the each of the second redundant signal lines and the one of the second auxiliary signal lines.

In some embodiments, the display panel further includes: a first power signal line, wherein the second redundant signal lines are electrically connected to the first power signal line, and/or the second auxiliary signal lines are electrically connected to the first power signal line.

In some embodiments, each of the plurality of light-emitting devices includes an anode, a light-emitting layer, and a cathode layer that are stacked, wherein the anode is closer to the base substrate relative to the cathode layer,
each of the plurality of first pixel circuits is electrically connected to an anode in a corresponding light-emitting devices in the plurality of light-emitting devices, and the cathode layer is electrically connected to the first power signal line.

In some embodiments, the display panel further has a non-display region on a periphery of the display region; and
the display panel further includes a plurality of connection leads in the non-display region and electrically connected to the plurality of data signal lines in one-to-one correspondence, wherein each of some of the plurality of connection leads is electrically connected to a corresponding data signal line in the plurality of data signal lines through the first lead portion and the second lead portion, and each of some of the plurality of connection leads is directly electrically connected to a corresponding data signal line in the plurality of data signal lines; and
the plurality of connection leads are configured to be bonded and connected to a driver assembly.

In some embodiments, the plurality of redundant signal lines and the plurality of data signal lines are disposed in a same layer and made of a same material, and the plurality of redundant signal lines and the plurality of auxiliary signal lines are disposed in different layers.

In some embodiments, the display panel further includes: a gate driver on array (GOA) circuit, wherein each of the plurality of light-emitting devices includes an anode, a light-emitting layer, and a cathode layer that are stacked, wherein the anode is closer to the base substrate relative to the cathode layer, and
an orthographic projection of the GOA circuit on the base substrate is overlapped with an orthographic projection of the anode on the base substrate.

In some embodiments, the display region includes a first display sub-region, a second display sub-region, and a third display sub-region, wherein
the second display sub-region is disposed between the first display sub-region and the third display sub-region, and the plurality of pixel circuits are disposed in the first display sub-region and the second display sub-region, and disposed outside the third display sub-region; at least part of the GOA circuit is disposed in the third display sub-region; and
pixel circuits in the plurality of pixel circuits disposed in the first display sub-region include the first pixel circuits and the dummy pixel circuits, all pixel circuits in the plurality of pixel circuits disposed in the second display sub-region are the first pixel circuits, some of the first pixel circuits in the second display sub-region are electrically connected to the plurality of light-emitting devices in the second display sub-region, and some of the first pixel circuits in the second display sub-region are electrically connected to the plurality of light-emitting devices in the third display sub-region.

In some embodiments, in the first display sub-region, a plurality of columns of the plurality of first pixel circuits are staggered with a plurality of columns of the plurality of dummy pixel circuits.

In some embodiments, N columns of the plurality of first pixel circuits are disposed between two adjacent columns of the plurality of dummy pixel circuits, wherein N is an integer greater than or equal to 2 and less than or equal to 6.

In some embodiments, a density of light-emitting devices in the plurality of light-emitting devices in the first display sub-region is equal to a density of light-emitting devices in the plurality of light-emitting devices in the second display sub-region.

In some embodiments, a plurality of columns of the plurality of first pixel circuits in the second display sub-region are correspondingly electrically connected to anodes of a plurality of columns of the plurality of light-emitting devices in the second display sub-region and in the third display sub-region.

In some embodiments, the display panel further includes: a plurality of transparent connection lines in the second display sub-region and in the third display sub-region,
wherein anodes of at least some of the plurality of light-emitting devices in the second display sub-region and in the third display sub-region are electrically connected to corresponding first pixel circuits through the plurality of transparent connection lines.

In some embodiments, the display panel further includes: a plurality of auxiliary signal lines, wherein some of the plurality of auxiliary signal lines are disposed in the second display sub-region and the third display sub-region; and
each of the plurality of transparent connection lines includes a first transparent lead portion and a second transparent lead portion that are connected to each other, wherein an extension direction of the first transparent lead portion is coincident with an extension direction of the plurality of auxiliary signal lines, and an extension direction of the second transparent lead portion is intersected with the extension direction of the plurality of auxiliary signal lines;
wherein an orthographic projection of the first transparent lead portion on the base substrate is not coincident with an orthographic projection of each of the plurality of auxiliary signal lines on the base substrate, and an orthographic projection of the second transparent lead portion in each of at least some of the plurality of transparent connection lines is overlapped with the orthographic projection of each of the plurality of auxiliary signal lines on the base substrate.

In some embodiments, a ratio of an overlapping area of an orthographic projection of at least one of the plurality of transparent connection lines on the base substrate and an orthographic projection of at least one of the plurality of auxiliary signal lines on the base substrate to a total area of the orthographic projection of the at least one of the plurality of transparent connection lines on the base substrate is less than or equal to 30%.

In some embodiments, an orthographic projection of each of the anodes of at least some of the plurality of light-emitting devices in the second display sub-region and in the third display sub-region on the base substrate is overlapped with orthographic projections of at least two of the plurality of transparent connection lines on the base substrate.

In some embodiments of the present disclosure, a display device is provided. The display device includes: a power supply, and a display panel electrically connected to the power supply, wherein the display panel is above display panel.

### BRIEF DESCRIPTION OF DRAWINGS

For a clearer description of the technical solutions in the embodiments of the present disclosure, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a top view of a display panel according to some embodiments of the present disclosure;

FIG. 2 is a locally enlarged diagram of the display panel in FIG. 1 at an A1 position;

FIG. 3 is a schematic structural diagram of film layers of the display panel in FIG. 2 at a B-B′ position;

FIG. 4 is a schematic connection diagram of a plurality of light-emitting devices and a plurality of first pixel circuits according to some embodiments of the present disclosure;

FIG. 5 is a locally top view of a display panel according to some embodiments of the present disclosure;

FIG. 6 is a schematic structural diagram of film layers of the display panel in FIG. 5 at a C-C′ position;

FIG. 7 is a top view of a display panel according to some embodiments of the present disclosure;

FIG. 8 is a schematic distribution diagram of redundant signal lines and auxiliary signal lines according to some embodiments of the present disclosure;

FIG. 9 is a schematic structural diagram of film layers of the display panel in FIG. 8 at a D-D′ position;

FIG. 10 is a schematic structural diagram of film layers of a display panel in a display region according to some embodiments of the present disclosure;

FIG. 11 is a locally top view of a display panel according to some embodiments of the present disclosure;

FIG. 12 is a top view of a display panel according to some embodiments of the present disclosure;

FIG. 13 is a top view of a display panel according to some embodiments of the present disclosure;

FIG. 14 is a locally enlarged diagram of the display panel in FIG. 12 at an A2 position;

FIG. 15 is a schematic connection diagram of a plurality of light-emitting devices and a plurality of first pixel circuits according to some embodiments of the present disclosure;

FIG. 16 is a schematic electrical connection diagram of light-emitting devices and first pixel circuits in the display panel in FIG. 12 at an A3 position;

FIG. 17 is a schematic connection diagram of anodes of light-emitting devices and first pixel circuits according to some embodiments of the present disclosure;

FIG. 18 is a schematic distribution diagram of a transparent connection line and an auxiliary signal line according to some embodiments of the present disclosure;

FIG. 19 is a schematic diagram of a relative position relationship of an anodes of a light-emitting device and transparent connection lines according to some embodiments of the present disclosure; and

FIG. 20 is a schematic structural diagram of film layers of the display panel in FIG. 19 at an E-E′ position.

### DETAILED DESCRIPTION

In order to make the objects, technical solutions and advantages of the present disclosure clearer, the embodiments of the present disclosure will be described in further detail below in conjunction with the accompanying drawings.

The display device generally includes a display panel and a driver chip. The display panel includes a display region and a non-display region, and the display panel includes: a plurality of subpixels and a plurality of data signal lines disposed in the display region, and a plurality of fan-out leads disposed in the non-display region. Each of the plurality of data signal lines is electrically connected to one column of subpixels, and each of the plurality of data signal lines is electrically connected to the driver chip through one of the plurality of fan-out leads. As such, the driver chip transmits a drive signal to the data signal lines through the fan-out leads to enable the display panel to display images.

However, in above display panel, the fan-out leads occupy a large space, such that a width of a region of the fan-out leads in the non-display region is large, a screen ratio of the display device is low, and a display effect of the display device is affected.

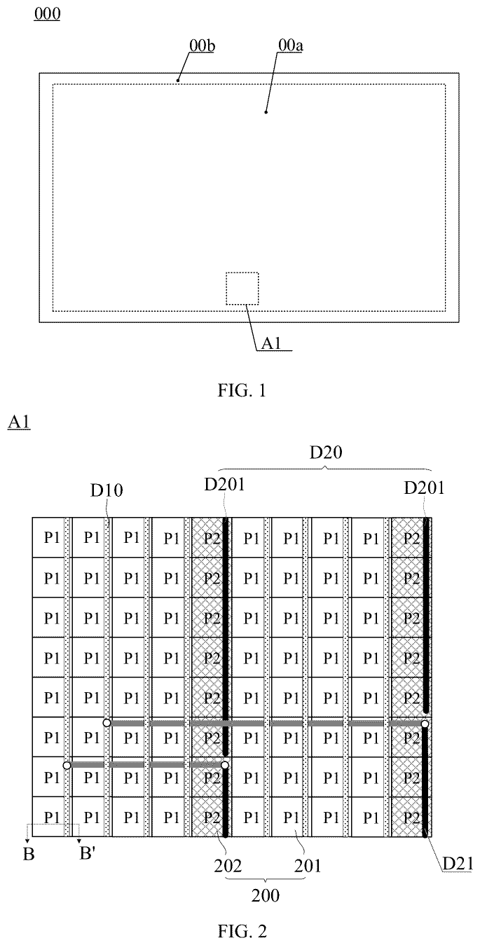

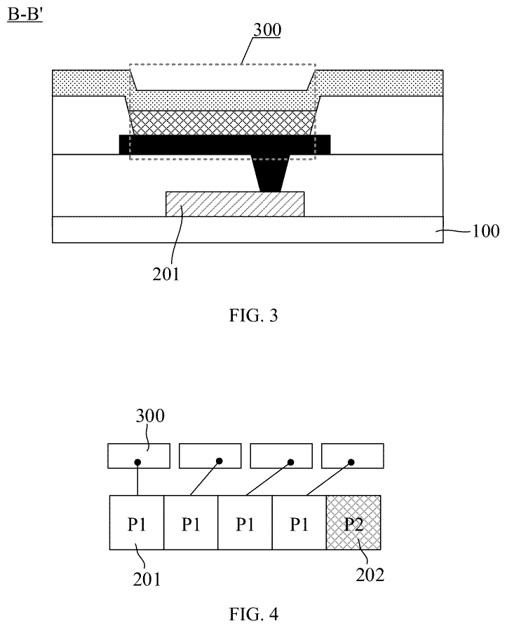

Referring to FIG. 1, FIG. 2, and FIG. 3, FIG. 1 is a top view of a display panel according to some embodiments of the present disclosure, FIG. 2 is a locally enlarged diagram of the display panel in FIG. 1 at an A1 position, and FIG. 3 is a schematic structural diagram of film layers of the display panel in FIG. 2 at a B-B′ position. The display panel 000 has a display region 00a and a non-display region 00b on a periphery of the display region 00a. The display panel 000 includes a base substrate 100, a plurality of pixel circuits 200, a plurality of light-emitting devices 300, a plurality of data signal lines D10, and a plurality of redundant signal lines D20.

The plurality of pixel circuits 200 in the display panel 000 are arrayed on a side of the base substrate 100, and are disposed in the display region 00a. The plurality of pixel circuits 200 include a plurality of first pixel circuits 201 and a plurality of dummy pixel circuits 202. The plurality of first pixel circuits 201 are arranged in a plurality of columns, the plurality of dummy pixel circuits 202 are arranged in a plurality of columns, and the plurality of columns of dummy pixel circuits 202 are interspersed in the plurality of columns first pixel circuits 201. A quantity of columns of first pixel circuits 201 is greater than a quantity of columns of dummy pixel circuits 202, and thus at least two columns of first pixel circuits 201 are disposed in two adjacent columns of dummy pixel circuits 202. It should be noted that FIG. 2 does not show the light-emitting devices 300 in the display panel 00 for a clearer distribution relationship of the plurality of pixel circuits 200 in the display panel 000. In addition, in FIG. 2, each box P1 represents a first pixel circuit 201, and each box P2 represents a dummy pixel circuit 202.

The plurality of light-emitting devices 300 in the display panel 000 are disposed on a side of the plurality of pixel circuits 200 away from the base substrate 100, and are disposed in the display region 00a. For a clearer connection relationship of the plurality of light-emitting devices 300 and the plurality of first pixel circuits 201, referring to FIG. 4, FIG. 4 is a schematic connection diagram of a plurality of light-emitting devices and a plurality of first pixel circuits according to some embodiments of the present disclosure. The plurality of light-emitting devices 300 are electrically connected to the plurality of first pixel circuits 201 in one-to-one correspondence, and each of the plurality of first pixel circuits 201 is configured to drive a corresponding light-emitting device 300 to emit light, such that the display region 00a of the display panel 00 displays a corresponding image. It should be noted that the dummy pixel circuit 202 does not need to be insulated from the light-emitting device 300, that is, the dummy pixel circuit 202 is not electrically connected to the light-emitting device 300.

The plurality of data signal lines D10 and the plurality of redundant signal lines D20 in the display panel 000 are disposed in the display region 00a, and an extension direction of the plurality of data signal lines D10 is coincident with an extension direction of the plurality of redundant signal lines D20.

The plurality of data signal lines D10 are in one-to-one correspondence with a plurality of columns of first pixel circuits 201, and each of the plurality of data signal lines D10 is disposed in a region of one corresponding column of first pixel circuits 201 and is electrically connected to first pixel circuits 201 in the corresponding column of first pixel circuits 201. In addition, the data signal line D10 is insulated from the dummy pixel circuit 202. That is, the data signal line D10 is not electrically connected to the dummy pixel circuit 202.

The plurality of redundant signal lines D20 are in one-to-one correspondence with a plurality of columns of dummy pixel circuits 202, and each of the plurality of redundant signal lines D20 is disposed in a region of one corresponding column of dummy pixel circuits 202 and needs to be insulated from dummy pixel circuits in the corresponding column of dummy pixel circuits 202. That is, the redundant signal line D20 is not electrically connected to the dummy pixel circuit 202.

It should be noted that the plurality of first pixel circuits 201 and the plurality of dummy pixel circuits 202 in the display panel 000 are formed by a same process simultaneously, and the data signal line D10 electrically connected to one column of first pixel circuits 201 is simultaneously formed in the process of forming the plurality of first pixel circuits 201. Thus, the redundant signal line D20 is simultaneously formed in a region of one column of dummy pixel circuits 202 in the process of forming the plurality of dummy pixel circuits 202, and the redundant signal line D20 needs to be insulated from dummy pixel circuits 202 in the column of dummy pixel circuits 202.

In the present disclosure, at least some of the plurality of redundant signal lines D20 in the display panel 000 are first redundant signal lines D201. One of the first redundant signal lines D201 includes a first lead portion D21 connected to one of the plurality of data signal lines D10. The first lead portion D21 acts as part of a fan-out lead electrically connected to the one of the plurality of data signal lines D10. As the plurality of redundant signal lines D20 are disposed in the display region 00a, the part (that is, the first lead portion) in the fan-out lead electrically connected to the one of the plurality of data signal lines D10 is disposed in the display region 00a, such that other part in the fan-out lead than the first lead portion D21 occupies a decreased space in the non-display region 00b in a case where the other part is disposed in the non-display region 00b, and a width of a region provided with the fan-out lead in the non-display region 00b is efficiently reduced. As such, a screen ratio of a display device equipped with the display panel 00 is effectively improved, such that a display effect of the display device is great.

It should be noted that in some practices, an additional signal lead electrically connected to the data signal line is disposed between two adjacent columns of sub-pixels, and the signal lead acts as part of the fan-out lead in the display region. However, some regions in the display panel need to be provided with signal leads, and some regions do not need to be provided with signal leads, such that conductive patterns for forming the signal leads in the display panel are not evenly distributed in the display region, and the display panel is prone to poor display problems, such as color bias.

In some embodiments of the present disclosure, the plurality of data signal lines D10 and the plurality of redundant signal lines D20 in the display panel 000 are disposed in a same layer and made of a same material. That is, the plurality of data signal lines D10 and the plurality of redundant signal lines D20 are formed by a one patterning process. That is, the plurality of data signal lines D10 and the plurality of redundant signal lines D20 in the display panel 000 are disposed in the same conductive pattern. As the plurality of columns of dummy pixel circuits 202 are interspersed in the plurality of columns first pixel circuits 201, the plurality of redundant signal lines D20 in the display panel 000 are interspersed in the plurality of data signal lines D10. As such, the conductive pattern including the data signal lines D10 and the redundant signal lines D20 are evenly disposed in the display region 00a. In a case where part of the first redundant signal line D201 in the region of one column of dummy pixel circuits 202 acts as the part of the fan-out lead in the display region 00a, the conductive layer patterns in the display panel 000 are evenly distributed in the display region 00a on the premise that the part of the fan-out lead is distributed in the display region 00a, such that the probability of color bias in the display panel 000 is effectively reduced, and the display effect of the display panel 000 is great.

In summary, the display panel according to the embodiments of the present disclosure includes the base substrate, the plurality of pixel circuits, the plurality of light-emitting devices, the plurality of data signal lines, and the plurality of redundant signal lines. One of the plurality of redundant signal lines includes a first lead portion connected to one of the plurality of data signal lines. The first lead portion acts as part of a fan-out lead electrically connected to the one of the plurality of data signal lines. As the plurality of redundant signal lines are disposed in the display region, the part (that is, the first lead portion) in the fan-out lead electrically connected to the one of the plurality of data signal lines is disposed in the display region, such that other part in the fan-out lead than the first lead portion occupies a decreased space in the non-display region in a case where the other part is disposed in the non-display region, and a width of a region provided with the fan-out lead in the non-display region is efficiently reduced. As such, a screen ratio of a display device equipped with the display panel is effectively improved, such that a display effect of the display device is great. In addition, the plurality of data signal lines and the plurality of redundant signal lines are disposed in the same conductive pattern, and the conductive patterns including the data signal lines and the redundant signal lines are evenly distributed in the display region. Therefore, in a case where part of the first redundant signal line in a region of one column of dummy pixel circuits acts as the part of the fan-out lead in the display region, conductive layer patterns in the display panel are evenly distributed in the display region on the premise that the part of the fan-out lead is distributed in the display region, such that a probability of color bias in the display panel is effectively reduced, and the display effect of the display panel is great.

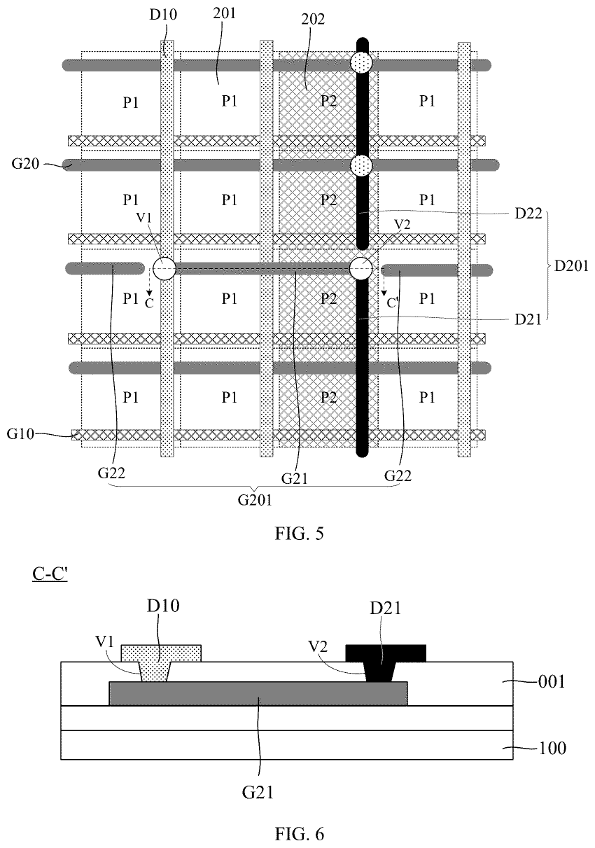

In the embodiments of the present disclosure, as shown in FIG. 5, FIG. 5 is a locally top view of a display panel according to some embodiments of the present disclosure. The display 000 further includes gate lines G10. An extension direction of the gate lines G10 is intersected with an extension direction of the data signal lines D10, For example, the extension direction of the gate lines G10 is perpendicular to the extension direction of the data signal lines D10.

The plurality of pixel circuits 200 in the display panel 000 are arranged in a plurality of rows, the plurality rows of pixel circuits 200 are in one-to-one correspondence with the plurality of gate lines G10, each of the plurality of gate lines G10 is disposed in a region of one corresponding row of pixel circuits 200, and each of the plurality of gate lines G10 is electrically connected to the first pixel circuits 201 in the corresponding row of pixel circuits 200. In addition, the gate line G10 is insulated from the dummy pixel circuit 202, that is, the gate line G10 is not electrically connected to the dummy pixel circuit 202.

In some embodiments, as shown in FIG. 5, the display panel 000 further includes a plurality of auxiliary signal lines G20 in the display region 00a. An extension direction of the plurality of auxiliary signal lines G20 is intersected with the extension direction of the plurality of redundant signal lines D20. For example, the extension direction of the plurality of auxiliary signal lines G20 is perpendicular to the extension direction of the plurality of redundant signal lines D20.

In the present disclosure, the extension direction of the plurality of auxiliary signal lines G20 is coincident with the extension direction of the gate lines G10. It should be noted that as a density of the gate lines G10 in the display panel 000 is great, the auxiliary signal lines G20 and the gate lines G10 are disposed in different layers even if the extension direction of the plurality of auxiliary signal lines G20 is coincident with the extension direction of the gate lines G10. That is, a conductive pattern of the auxiliary signal lines G20 and a conductive pattern of the gate lines G10 are different conductive patterns, and an insulated layer is disposed between the conductive pattern of the auxiliary signal lines G20 and the conductive pattern of the gate lines G10.

The auxiliary signal lines G20 and the redundant signal lines D20 are disposed in different layers. That is, the conductive pattern of the auxiliary signal lines G20 and a conductive pattern of the redundant signal lines D20 are different conductive patterns, and an insulated layer is disposed between the conductive pattern of the auxiliary signal lines G20 and the conductive pattern of the redundant signal lines D20. As such, the short-circuit phenomenon does not occur between the auxiliary signal lines G20 and the data signal lines D10, and the short-circuit phenomenon does not occur between the gate lines G10 and the data signal lines D10.

The plurality of auxiliary signal lines G20 in the display panel 000 are in one-to-one correspondence with the plurality of rows of pixel circuits 200, and each of the plurality of auxiliary signal lines G20 is disposed in a region of one corresponding row of pixel circuits 200 and is insulated from pixel circuits in the corresponding row of pixel circuits 200. That is, the auxiliary signal lines G20 are not electrically connected to the pixel circuits 200.

In the present disclosure, at least some of the plurality of auxiliary signal lines G20 are first auxiliary signal lines G201. One of the plurality of auxiliary signal lines G20 includes a second lead portion G21. One end of the second lead portion G21 is electrically connected to one of the plurality of data signal lines D10, and another end of the second lead portion G21 is electrically connected to an end of the first lead portion D21. In this case, the part of the fan-out lead connected to the data signal line D10 in the display region 00a includes the second lead portion G21 and the first lead portion D21. In a case where a plurality of fan-out leads in the display panel are bonded and connected to a driver chip, a drive signal is transmitted to the data signal line D10 upon running through the part of the fan-out lead in the non-display region 00b, the first lead portion D21, and the second lead portion G21.

As an auxiliary signal line G20 is disposed in each row of pixel circuit 200, conductive patterns including the plurality of auxiliary signal lines G20 are evenly distributed in the display region 00a. The conductive patterns including the plurality of redundant signal lines D20 are also evenly distributed in the display region 00a. As such, in a case where part of the auxiliary signal line G20 and part of the redundant signal line D20 act as the part of the fan-out lead in the display region 00a, conductive layer patterns in the display panel are evenly distributed in the display region on the premise that the part of the fan-out lead is distributed in the display region 00a, such that the probability of color bias in the display panel is effectively reduced.

In some embodiments of the present disclosure, as shown in FIG. 6, FIG. 6 is a schematic structural diagram of film layers of the display panel in FIG. 5 at a C-C′ position. As an insulated layer 001 is disposed between a conductive pattern of the data signal lines D10 and a conductive pattern of the auxiliary signal lines G20, a first via V1 and a second via V2 that penetrate through the insulated layer 001 are disposed in the display panel 000, such that an end of the second lead portion G21 in the first auxiliary signal line G201 is lapped with the data signal line D10 through the first via V1, and another end of the second lead portion G21 in the first auxiliary signal line G201 is lapped with an end of the first lead portion G21 in the first redundant signal line D201 through the second via V2.

It should be noted that parts of the redundant signal lines D20 other than the first lead portions D21 do not load the drive signal, such that the parts are in a suspended state. In a case where the part of the redundant signal line D20 other than the first lead portion D21 is in the suspended state, the part of the redundant signal line D20 other than the first lead portion D21 interferes with a gate scan signal loaded on the gate line G10 crossed with the part. Similarly, parts of the auxiliary signal lines G20 other than the second lead portions G21 do not load the drive signal, such that the parts are in a suspended state. In a case where the part of the auxiliary signal line G20 other than the second lead portion G21 is in the suspended state, the part of the auxiliary signal line G20 other than the second lead portion G21 interfered with a data signal recorded on the data signal line D10 crossed with the part.

Thus, in the embodiments of the present disclosure, the parts of the redundant signal lines D20 other than the first lead portions D21 and the parts of the auxiliary signal lines G20 other than the second lead portions G21 are further processed to ensure that the signal lines do not interfere with the signals loaded on other signal lines.

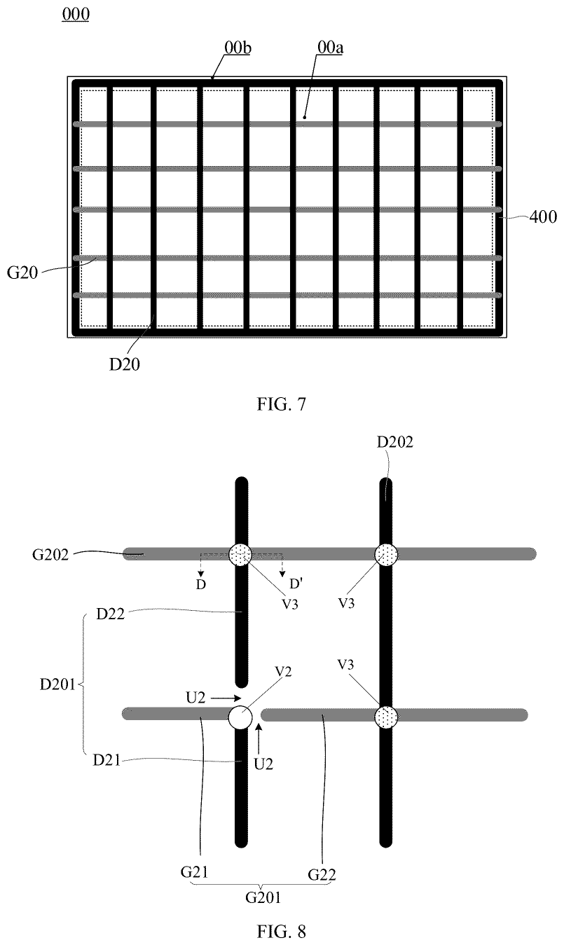

Illustratively, as shown in FIG. 7, FIG. 7 is a top view of a display panel according to some embodiments of the present disclosure. The display panel 000 further includes a first power signal line 400 in the non-display region 00b. The first power signal line 400 is a low level power signal line (that is, a VSS power signal line), and the first power signal line 400 is an annular power signal line.

The parts of the redundant signal lines D20 other than the first lead portions D21 are electrically connected to the first power signal line 400, and/or the parts of the auxiliary signal lines G20 other than the second lead portions G21 are electrically connected to the first power signal line 400. It should be noted that FIG. 7 is illustrated using an example where the parts of the redundant signal lines D20 other than the first lead portions D21 and the parts of the auxiliary signal lines G20 other than the second lead portions G21 are electrically connected to the first power signal line 400.

As such, as the VSS signal recorded on the first power signal line 400 has a fixed potential, the parts of the redundant signal lines D20 other than the first lead portions D21 load the VSS signal with a fixed potential in a case where the parts of the redundant signal lines D20 other than the first lead portions D21 are electrically connected to the first power signal line 400; the parts of the auxiliary signal lines G20 other than the second lead portions G21 load the VSS signal with a fixed potential in a case where the parts of the auxiliary signal lines G20 other than the second lead portions G21 are electrically connected to the first power signal line 400. In this way, the parts of the redundant signal lines D20 other than the first lead portions D21 and the parts of the auxiliary signal lines G20 other than the second lead portions G21 are not in the suspended state, such that the parts of the redundant signal lines D20 other than the first lead portions D21 do not interfere with the gate line G10, and the parts of the auxiliary signal lines G20 other than the second lead portions G21 do not interfere with the data line D1.

In some embodiments, parts of the redundant signal lines D20 other than the first lead portions D21 are electrically connected to the parts of the auxiliary signal lines G20 other than the second lead portions G21. As such, as long as one of the parts of the redundant signal lines D20 other than the first lead portions D21 and the parts of the auxiliary signal lines G20 other than the second lead portions G21 are connected the first power signal line 400, the first power signal line 400 provides the VSS signals to the parts of the redundant signal lines D20 other than the first lead portions D21 and the parts of the auxiliary signal lines G20 other than the second lead portions G21.

Illustratively, as shown in FIG. 8, FIG. 8 is a schematic distribution diagram of redundant signal lines and auxiliary signal lines according to some embodiments of the present disclosure. In addition to the first lead portion D21, one of the first redundant signal lines D200 further includes a redundant line body D22 disconnected to the first lead portion D21. For example, a first partition Ul is disposed between the first lead portion D21 and the redundant line body D22 in the first redundant signal line D201, and the first lead portion D21 is insulated from the redundant line body D22 through the first partition U1. In addition to the second lead portion G21, one of the first auxiliary signal lines G201 further includes an auxiliary line body G22 disconnected from the second lead portion G21. For example, a second partition U2 is disposed between the second lead portion G21 and the auxiliary line body G22 in the first auxiliary signal line G201, and the second lead portion G21 is insulated from the auxiliary line body G22 through the second partition U2.

The redundant line body D22 in the first redundant signal line D201 is electrically connected to the auxiliary line body G22 in the first auxiliary signal line G201 at an intersection between the redundant line body D22 and the auxiliary line body G22, such that the part of the first redundant signal line D201 other than the first lead portion D21 is electrically connected to the part of the first auxiliary signal line G201 other than the second lead portion G21.

It should be noted that not all redundant signal lines D20 in the display panel 000 need to be provided with the first lead portion D21, and not all auxiliary signal lines G20 need to be provided with the second lead portion G21.

Thus, some of the plurality of redundant signal lines D20 in the display panel 000 are the first redundant signal lines D201, and some of the plurality of redundant signal lines D20 are the second redundant signal lines D202. The first redundant signal line D201 includes the first lead portion D21 and the redundant line body D22, the second redundant signal line D202 is not provided with the first lead portion D21 and is a whole signal line, and a partition is not provided in the second redundant signal line D202. The second redundant signal line D202 is electrically connected to the auxiliary line body G22 in the first auxiliary signal line G201 at an intersection between the second redundant signal line D202 and the auxiliary line body G22.

And/or, some of the plurality of auxiliary signal lines G20 in the display panel 000 are the first auxiliary signal lines G201, and some of the plurality of auxiliary signal lines G20 are the second auxiliary signal lines G202. The first auxiliary signal line G201 includes the second lead portion G21 and the auxiliary line body G22, the second auxiliary signal line G202 is not provided with the second lead portion G21 and is a whole signal line, and a partition is not provided in the second auxiliary signal line G202. The second auxiliary signal line G202 is electrically connected to the redundant line body D22 in the first redundant signal line D201 at an intersection between the second auxiliary signal line G202 and the redundant line body D22.

In the embodiments of the present disclosure, in a case where the display panel 000 includes the second redundant signal line D202 and the second auxiliary signal line G202, the second redundant signal line D202 is electrically connected to the second auxiliary signal line G202 at an intersection between the second redundant signal line D202 and the second auxiliary signal line G202.

In this case, in the display panel 000, the parts of the redundant signal lines D20 other than the first lead portions D21 are electrically connected to the parts of the auxiliary signal lines G20 other than the second lead portions G21 at intersections of the parts of the redundant signal lines D20 other than the first lead portions D21 and the parts of the auxiliary signal lines G20 other than the second lead portions G21. In addition, the parts of the redundant signal lines D20 other than the first lead portions D21 and the parts of the auxiliary signal lines G20 other than the second lead portions G21 form a mesh conductive layer in the display panel 000.

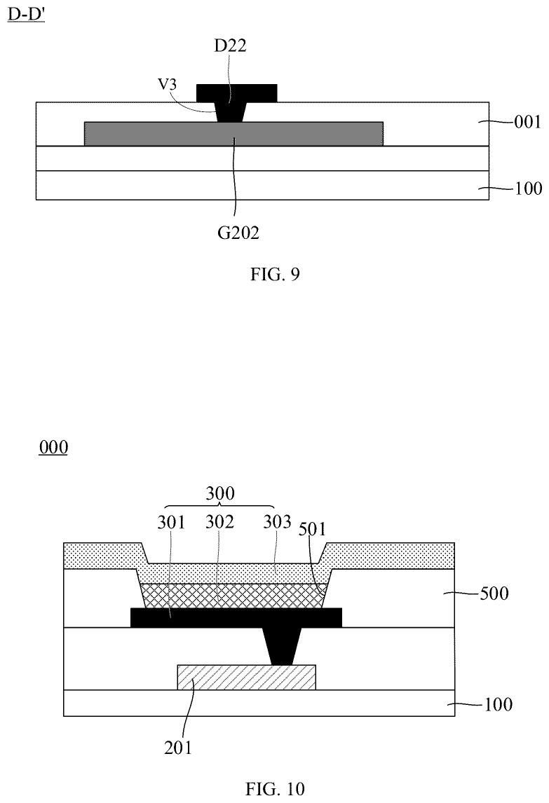

For example, referring to FIG. 9, FIG. 9 is a schematic structural diagram of film layers of the display panel in FIG. 8 at a D-D′ position. As an insulated layer 001 is disposed between a conductive pattern of the redundant signal lines D20 and a conductive pattern of the auxiliary signal lines G20, a third via V3 that penetrates through the insulated layer 001 is disposed in the display panel 000, such that the parts of the redundant signal lines D20 other than the first lead portions D21 are lapped with the parts of the auxiliary signal lines G20 other than the second lead portions G21 through the third via V3.

In the present disclosure, an end portion of the second redundant signal line D202 is electrically connected to the first power signal line 400, and/or an end portion of the second auxiliary signal line G202 is electrically connected to the first power signal line 400. And end portion of the redundant line body D22 in the first redundant signal line D201 is electrically connected to the first power signal line 400, and/or an end portion of the auxiliary line body G22 in the second auxiliary signal line G 202 is electrically connected to the first power signal line 400. As such, the mesh conductive layer in the display panel 000 formed by the parts of the redundant signal lines D20 other than the first lead portions D21 and the parts of the auxiliary signal lines G20 other than the second lead portions G21 is connected to the first power signal line 400.

In the embodiments of the present disclosure, as shown in FIG. 10, FIG. 10 is a schematic structural diagram of film layers of a display panel in a display region according to some embodiments of the present disclosure. The light-emitting device 300 in the display panel 000 includes an anode 301, a light-emitting layer 302, and a cathode layer 303 that are stacked. The anode 301 of the light-emitting device 300 is closer to the base substrate 100 relative to the cathode layer 303.

In some embodiments, the display panel further includes a pixel definition layer 500. A conductive pattern of the anode 301 is closer to the base substrate 100 relative to the pixel definition layer 500, the cathode layer 303 is disposed on a side of the pixel definition layer 500 facing away from the base substrate 100, and the light-emitting layer 302 is disposed between the anode 301 and the cathode layer 303. Pixel hole 501 in one-to-one correspondence to the plurality of light-emitting devices 300 are defined in the pixel definition layer 500, and an orthographic projection of each pixel hole 501 on the base substrate 100 is within an orthographic projection of the anode 301 of the corresponding light-emitting device 300 on the base substrate 100. It should be noted that both the light-emitting layer 302 and the cathode layer 303 are film layer structures disposed in the whole layer. Therefore, in the display panel 000, part of the anode 301 in the corresponding pixel hole 501, part of the light-emitting layer 302 in the pixel hole 501, and part of the cathode layer 303 in the pixel hole 501 form a light-emitting device 300. For example, the light-emitting device 300 is an organic light-emitting diode (OLED) device.

In the present disclosure, each first pixel circuit 201 in the display panel 000 is electrically connected to the anode 301 in the corresponding light-emitting device 300, and the cathode in the corresponding light-emitting device 300 is electrically connected to the first power signal line 400.

As the cathode layer 303 in the display panel 000 is the film layer structure disposed in the whole layer, the first power signal line 400 provides the VSS signal to various light-emitting devices in a case where the cathode layer 303 is electrically connected to the first power signal line 400. As a thickness of the cathode layer is less, a resistance is usually large, and the mesh conductive layer formed by the parts of the redundant signal lines D20 other than the first lead portions D21 and the parts of the auxiliary signal lines G20 other than the second lead portions G21 is electrically connected to the cathode layer 303, the mesh conductive layer acts as an auxiliary electrode of the cathode layer 303. Therefore, the resistance of the cathode layer 303 is reduced through the mesh conductive layer, such that the VSS signals at various positions of the cathode layer 303 are consistent, and the uniformity of the VSS signals applied to the cathode layer 303 is ensured.

In some embodiments, the display panel 000 further includes a second power signal line (not shown in the drawing). At least part of the second power signal line is disposed in the display region 00a, and the second power signal line is electrically connected to various first pixel circuits 201 in the display region 00a. The second power signal line is a high level power signal line (that is, a VDD power signal line), and a VDD signal is supplied to various first pixel circuits 201 over the second power signal line, such that the first pixel circuit 201 drives the corresponding light-emitting device to emit light.

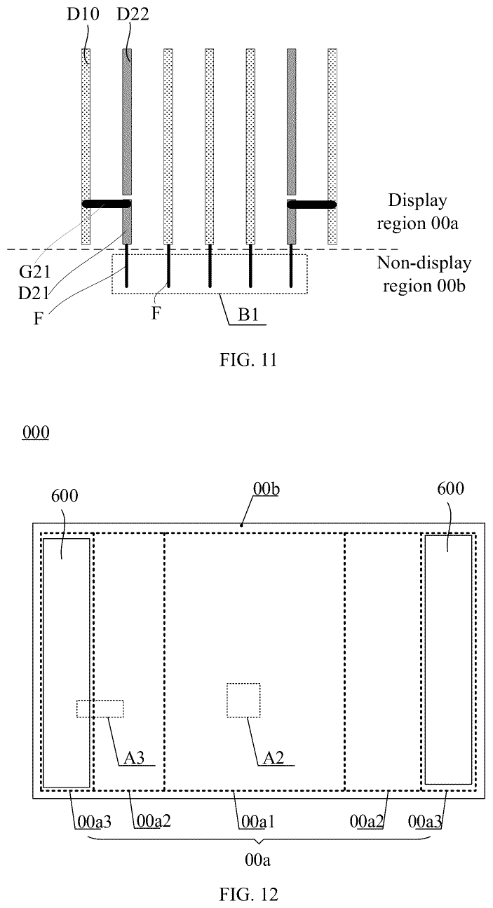

In the embodiments of the present disclosure, as shown in FIG. 11, FIG. 11 is a locally top view of a display panel according to some embodiments of the present disclosure. The display panel 000 further includes a plurality of connection leads F in one-to-one correspondence with the plurality of data signal lines D10. The plurality of connection leads F are disposed in the non-display region 00b in the display panel 000. Each of some of the plurality of connection leads F is electrically connected to a corresponding data signal line D10 through the first lead portion D21 and the second lead portion G21. In a case where the connection lead F is electrically connected to a corresponding data signal line D10 through the first lead portion D21 and the second lead portion G21, the connection lead F, the first lead portion D21, and the second lead portion G21 form a fan-out lead corresponding to the data signal line D10. As such, part of the fan-out lead is disposed in the display region 00a, such that an occupied space of the fan-out lead in the non-display region 00b is efficiently reduced. Each of some of the plurality of connection leads F is directly electrically connected to a corresponding data signal line D10 in the plurality of data signal lines D10. In a case where the connection lead F is directly electrically connected to the data signal line D10, the connection lead F is a fan-out lead corresponding to the data signal line D10.

In the present disclosure, the plurality of connection leads F in the non-display region 00b are configured to be bonded and connected to a driver assembly. For example, the driver assembly is bonded to a position B1 in the non-display region 00b, such that the driver assembly supplies the data signal to the corresponding data signal line D10 over the connection lead F.

Illustratively, the plurality of data signal lines D1 are connected to the driver chip by gathering the plurality of data signal lines D1 from both sides to the center to connect the plurality of data signal lines D10 in the display panel 000 to the driver chip. In addition, as the data signal lines D10 on both sides of the bonding position B1 of the driver chip are farther away from the driver chip, and the data signal lines D10 in the center are closer to the drive chip, the data signal lines D10 on both sides need to be connected to the corresponding connection lead F through the second lead portion G21 and the first lead portion D21, and the data signal lines D10 in the center are directly connected to the corresponding connection lead F.

For the data signal lines D10 on both sides, the driver assembly supplies data signals to the data signal line D10 through the corresponding connection lead F, the first lead portion D21, and the second lead portion G21. For the data signal lines D10 in the center, the driver assembly supplies data signals directly to the data signal line D10 through the corresponding connection lead F.

In the embodiments of the present disclosure, as shown in FIG. 12, FIG. 12 is a top view of a display panel according to some embodiments of the present disclosure. The display panel 000 further includes a GOA circuit 600. At least part of the GOA circuit 600 is disposed in the display region 00a of the display panel 000. Two GOA circuits 600 are generally disposed, and the two GOA circuits 600 are disposed on two sides of the display panel 000. Two ends of each gate line G10 in the display panel 000 are electrically connected to the two GOA circuits 600, and gate scan signals are supplied to various gate lines G10 through the GOA circuits 600. In the present disclosure, as at least part of the GOA circuit 600 in the display panel 000 is disposed in the display region 00a, a width of the non-display region 00b of the display panel 000 is further reduced. In this way, the screen ratio of the display device equipped with the display panel is further improved.

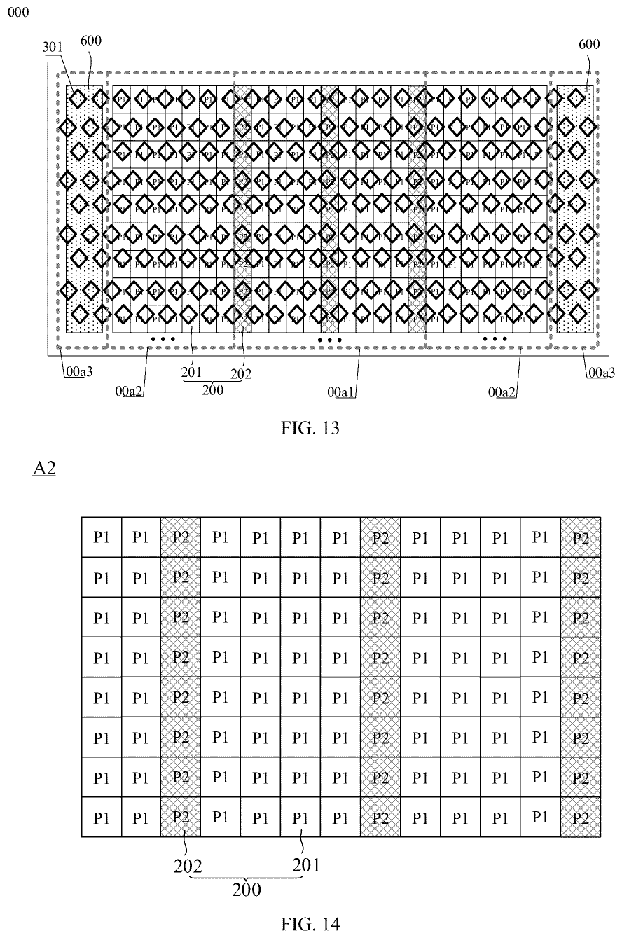

Illustratively, referring to FIG. 13, FIG. 13 is a top view of a display panel according to some embodiments of the present disclosure. An orthographic projection of the GOA circuit 600 in the display panel 000 on the base substrate 100 is overlapped with an orthographic projection of the anode of the light-emitting device 300 on the base substrate 100. As such, some of the plurality of light-emitting devices 300 in the display panel 000 are disposed on a side of the GOA circuit 600 facing away from the base substrate 100, such that a region provided with the GOA circuit 600 in the display panel 000 displays images normally.

In the present disclosure, the display region 00a in the display panel 000 includes a first display sub-region 00a1, a second display sub-region 00a2, and a third display sub-region 00a3. The second display sub-region 00a2 is disposed between the first display sub-region 00a1 and the third display sub-region 00a3, and the light-emitting devices 300 are disposed in the first display sub-region 00a1, the second display sub-region 00a2, and the third display sub-region 00a3, such that the three display sub-regions display images normally.

The plurality of pixel circuits 200 in the display panel 000 are disposed in the first display sub-region 00a1 and the second display sub-region 00a2, and disposed outside the third display sub-region 00a3. At least part of the GOA circuit 600 in the display panel 000 is disposed in the third display sub-region 00a3. It should be noted that as the pixel circuit 200 and the GOA circuit 600 generally include a transistor, and the transistor in the pixel circuit 200 and the transistor in the GOA circuit 600 are generally formed simultaneously, the pixel circuit 200 is disposed outside the third display region 00a3 and at least part of the GOA circuit 600 is disposed in the third display region 00a3, such that a position of the GOA circuit 600 does not interferes with a position of the pixel circuit 200 on the premise that the GOA circuit 600 is disposed in the display region 00a.

In the present disclosure, pixel circuits 200 in the plurality of pixel circuits 200 disposed in the first display sub-region 00a1 include the first pixel circuits 201 and the dummy pixel circuits 202, all pixel circuits 200 in the plurality of pixel circuits 200 disposed in the second display sub-region 00a2 are the first pixel circuits 201, some of the first pixel circuits 201 in the second display sub-region 00a2 are electrically connected to the plurality of light-emitting devices 300 in the second display sub-region 00a2, and some of the first pixel circuits 201 in the second display sub-region 00a2 are electrically connected to the plurality of light-emitting devices 300 in the third display sub-region 00a3.

It should be noted that in the first display sub-region 00a, a plurality of columns of the plurality of first pixel circuits 201 are staggered with a plurality of columns of the plurality of dummy pixel circuits 202. A quantity of columns of the first pixel circuits 201 is greater than a quantity of columns of dummy pixel circuits 202, and thus at least two columns of first pixel circuits 201 are disposed between two adjacent columns of dummy pixel circuits 202. In this case, compared with the display panel in some practices in which the plurality of pixel circuits are electrically connected to the plurality of light-emitting devices in one-to-one correspondence, the plurality of pixel circuits 200 in the display panel 000 according to the embodiments of the present disclosure are acquired by compressing the plurality of pixel circuits in the display panel in some practices in a row direction. Thus, in the embodiments of the present disclosure, a quantity of the pixel circuits 200 is greater than a quantity of light-emitting devices 300, and a width of the pixel circuit 200 is much smaller than a width of the light-emitting device 300 in the row direction in the display panel 000 according to the embodiments of the present disclosure.

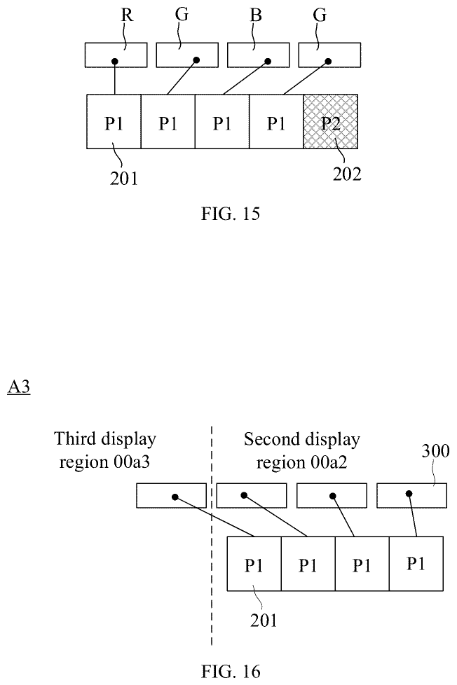

Illustratively, as shown in FIG. 14, FIG. 14 is a locally enlarged diagram of the display panel in FIG. 12 at an A2 position. In the first display sub-region 00a1 of the display panel 000, a ratio of the quantity of columns of the first pixel circuits 201 to the quantity of columns of dummy pixel circuits 202 is N:1. That is, N columns of first pixel circuits 201 are disposed between two adjacent columns of dummy pixel circuits 202. N is an integer greater than or equal to 2 and less than or equal to 6. Referring to FIG. 15, FIG. 15 is a schematic connection diagram of a plurality of light-emitting devices and a plurality of first pixel circuits according to some embodiments of the present disclosure. In a case where N is equal to 4, in the first display sub-region 00a1, four columns of first pixel circuit 201 and one column of dummy pixel circuits 202 are disposed in a region of four columns of adjacent light-emitting devices 300, and the four columns of first pixel circuit 201 are electrically connected to the four columns of adjacent light-emitting devices 300 in one-to-one correspondence. It should be noted that the four adjacent columns of light-emitting devices 300 are: a column of light-emitting devices for emitting red light, a column of light-emitting devices for emitting blue light, and two columns of light-emitting devices for emitting green light. Thus, various light-emitting devices in the display panel 000 are arranged in an RGBB mode In the row direction of the plurality of light-emitting devices 300, a light-emitting device R for emitting red light, a light-emitting device B for emitting blue light, and two light-emitting devices G for emitting green light that are adjacent form a group of pixels.

In the embodiments of the present disclosure, a density of light-emitting devices 300 in the plurality of light-emitting devices 300 in the first display sub-region 00a1, a density of light-emitting devices 300 in the plurality of light-emitting devices 300 in the second display sub-region 00a2, and a density of light-emitting devices 300 in the plurality of light-emitting devices 300 in the third display sub-region 00a3 are equal. As such, a display effect of the first display sub-region 00a1 is basically the same as a display effect of the second display sub-region 00a2 and a display effect of the third display sub-region 00a3, such that an overall display effect of the display panel is effectively improved.

It should be noted that as two GOA circuits 600 are disposed in the display panel 000, two third display sub-regions 00a3 are required in the display region 00a, such that the two GOA circuits are disposed between the two third display sub-regions 00a3. As the second display sub-region 00a2 needs to be disposed between the third display sub-region 00a3 and the first display sub-region 00a1, two second display sub-regions 00a2 are required in the display region 00a. In this case, the first display sub-region 00a1 in the display region 00a needs to be disposed between two second display sub-regions 00a2, and the third display sub-region 00a3 needs to be disposed on the side of the second display sub-region 00a2 facing away from the first display sub-region 00a1.

In the embodiments of the present disclosure, a density of pixel circuits 200 in the first display sub-region 00a1 is equal to a density of pixel circuits 200 in the second display sub-region 00a2.

In this case, referring to FIG. 16, FIG. 16 is a schematic electrical connection diagram of light-emitting devices and first pixel circuits in the display panel in FIG. 12 at an A3 position. As all of the pixel circuits 200 in the second display sub-region 00a2 are the first pixel circuits 201, and a width of the pixel circuit 200 is much less than a width of the light-emitting device 300 in the row direction, a quantity of columns of first pixel circuits 201 is greater than a quantity of columns of light-emitting devices 300 in the second display sub-region 00a2. In this way, some of the first pixel circuits 201 in the second display sub-region 00a2 are electrically connected to the plurality of light-emitting devices 300 in the second display sub-region 00a2 in one-to-one correspondence, and some of the first pixel circuits 201 in the second display sub-region 00a2 do not need to be connected to the plurality of light-emitting devices 300 in the second display sub-region 00a2 and are electrically connected to the plurality of light-emitting devices 300 in the third display sub-region 00a3.

Illustratively, a quantity of columns of first pixel circuits 201 in the second display sub-region 00a2 is equal to a quantity of columns of light-emitting devices 300 in the second display sub-region 00a2 and in the third display sub-region 00a3. That is, the quantity of columns of first pixel circuits 201 in the second display sub-region 00a2 is equal to a sum of a quantity of columns of light-emitting devices 300 in the second display sub-region 00a2 and a quantity of columns of light-emitting devices 300 in the third display sub-region 00a3. As such, the plurality of columns of first pixel circuits 201 in the second display sub-region 00a2 are electrically connected to the plurality of light-emitting devices 300 in the second display sub-region 00a2 and in the third display sub-region 00a3 in one-to-one correspondence. That is, the plurality of columns of first pixel circuits 201 in the second display sub-region 00a2 are electrically connected to anodes of the plurality of light-emitting devices 300 in the second display sub-region 00a2 and in the third display sub-region 00a3. As such, the anodes of the light-emitting devices 300 in the third display sub-region 00a3 are connected to the first pixel circuits 201 in the second display sub-region 00a2 on the premise that the first pixel circuits 201 are not disposed in the third display sub-region 00a3, such that the GOA circuit 600 is disposed in the third display sub-region 00a3. As such, the GOA circuit 600 is hidden in the third display sub-region 00a3 in the display region 00a.

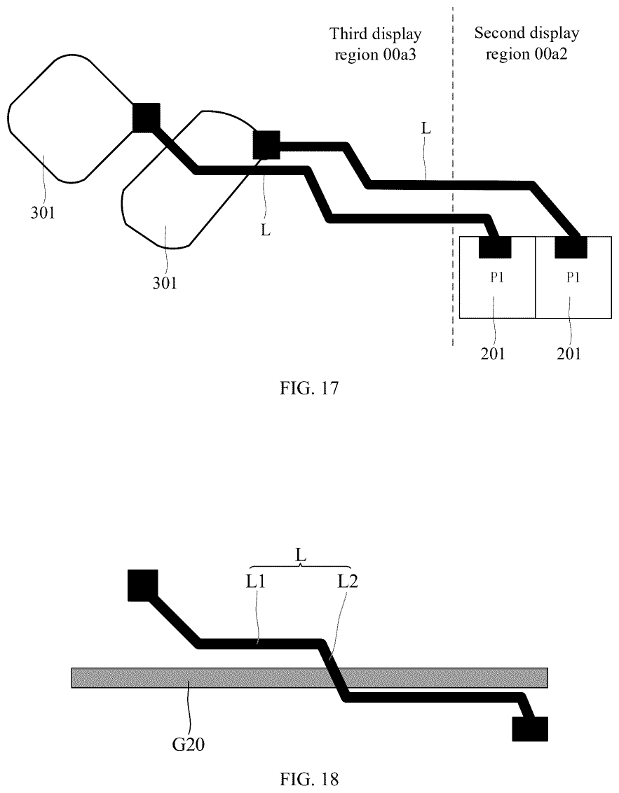

In the embodiments of the present disclosure, as shown in FIG. 17, FIG. 17 is a schematic connection diagram of anodes of light-emitting devices and first pixel circuits according to some embodiments of the present disclosure. The display panel 000 further includes a plurality of transparent connection lines L in the second display sub-region 00a2 and in the third display sub-region 00a3. Anodes 301 of at least some of the plurality of light-emitting devices 300 in the second display sub-region 00a2 and in the third display sub-region 00a3 are electrically connected to corresponding first pixel circuits 201 through the plurality of transparent connection lines L. As such, as the transparent connection line L has a greater transmittance to light and a less reflectivity to light, in a case where the anodes 301 of the light-emitting devices 300 in the second display sub-region 00a2 and in the third display sub-region 00a3 are connected to the first pixel circuits 201 through the transparent connection lines L, the reflectivity of the second display sub-region 00a2 and the third display sub-region 00a3 to the environmental light is basically consistent with the reflectivity of the first display sub-region 00a1 to the environmental light on the premise that the light-emitting devices 300 in the second display sub-region 00a2 and the third display sub-region 00a3 are normally connected to the corresponding first pixel circuits 201, such that the reliability of the display panel 000 is great.

In the embodiments of the present disclosure, as shown in FIG. 18, FIG. 18 is a schematic distribution diagram of a transparent connection line and an auxiliary signal line according to some embodiments of the present disclosure. The transparent connection line L includes a first transparent lead portion L1 and a second transparent lead portion L2 that are connected to each other. An extension direction of the first transparent lead portion L1 in the transparent connection line L is coincident with an extension direction of the auxiliary signal lines G20, and an extension direction of the second transparent lead portion L2 is intersected with the extension direction of the auxiliary signal lines G20.

In the present disclosure, an orthographic projection of the first transparent lead portion L1 in the transparent connection line L in the display panel 000 on the base substrate 100 is not coincident with an orthographic projection of each of the plurality of auxiliary signal lines G20 on the base substrate 100, and an orthographic projection of the second transparent lead portion L2 in each of at least some of the plurality of transparent connection lines L in the display panel 000 is overlapped with the orthographic projection of each of the plurality of auxiliary signal lines G20 on the base substrate 100. In this case, an overlapping area of the orthographic projection of the transparent connection line L in the display panel 000 on the base substrate 100 and the orthographic projection of the auxiliary signal line G20 on the substrate 100 is small, such that a parasitic capacitance between the transparent connection line L and the auxiliary signal line G20 is small. For example, a ratio of an overlapping area of an orthographic projection of at least one of the plurality of transparent connection lines L on the base substrate 100 and an orthographic projection of at least one of the plurality of auxiliary signal lines G20 on the base substrate 100 to a total area of the orthographic projection of the at least one of the plurality of transparent connection lines L on the base substrate 100 is less than or equal to 30%. In this way, in a case where the first pixel circuit 201 transmits signals to the anode 301 of the corresponding light-emitting device 300 through the transparent connection line L, the transparent connection line L is less interfered by the auxiliary signal line G20, such that the effect of light emitted by the light-emitting device 300 in the second display sub-region 00a2 and the third display sub-region 00a3 is great.

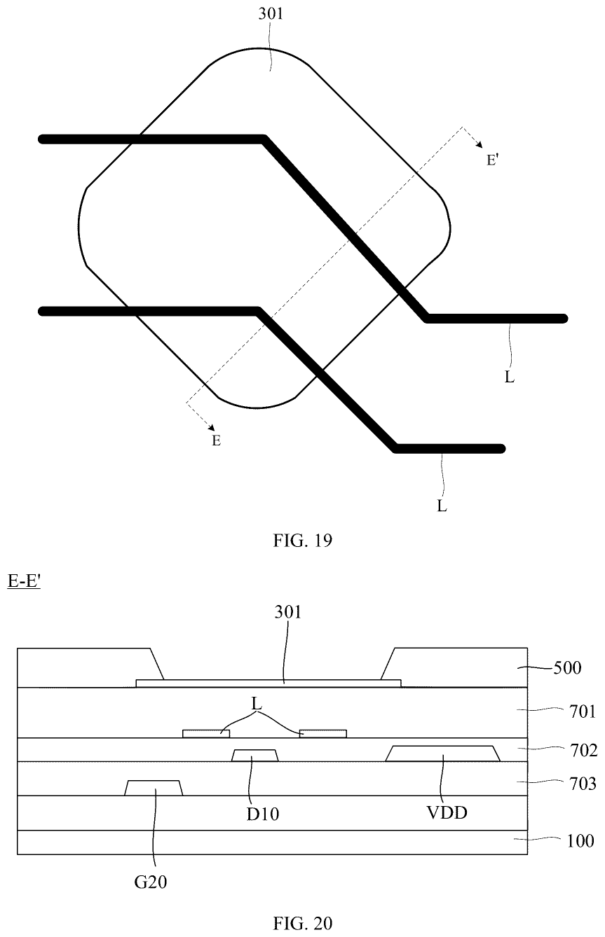

In some embodiments, referring to FIG. 19, FIG. 19 is a schematic diagram of a relative position relationship of an anodes of a light-emitting device and transparent connection lines according to some embodiments of the present disclosure. An orthographic projection of each of the anodes 301 of at least some of the plurality of light-emitting devices 300 in the second display sub-region 00a2 and in the third display sub-region 00a3 on the base substrate 100 is overlapped with orthographic projections of at least two of the plurality of transparent connection lines on the base substrate. The anode 301 and the transparent connection line L of which the orthographic projections are overlapped are not electrically connected to each other, that is, the transparent connection line L is electrically connected to the anode 301 of the corresponding light-emitting device 300 upon running through another light-emitting device 300.

In this case, referring to FIG. 20, FIG. 20 is a schematic structural diagram of film layers of the display panel in FIG. 19 at a E-E′ position. At least two transparent connection lines L are disposed below (that is, on a side close to the base substrate 100 of) the anode 301 of the light-emitting device 300, such that the flatness of the anode 301 is great, and the effect of the light emitted by the light-emitting device 300 is great.

In the embodiments of the present disclosure, as shown in FIG. 20, a first planarization layer 701 is disposed between a conductive layer of the transparent connection line L in the display panel 000 and a conductive layer of the anode 301. A conductive layer of the data signal line D10 in the display panel 000 is disposed on a side of the first planarization layer 701 facing towards the base substrate 100, and the data signal line D10 in the display panel 000 and the VDD power signal line are disposed in the same layer and made of the same material. A second planarization layer 702 is disposed between the conductive layer of the data signal line D10 and the conductive layer of the transparent connection line L. The auxiliary signal line G20 in the display panel 000 is disposed on a side of the second planarization layer 702 facing towards the base substrate 100, and a third planarization layer 703 is disposed between a conductive layer of the second auxiliary signal line G20 and the conductive layer of the data signal line D10.

It should be noted that various pixel circuits 200 and various GOA circuits 600 in the present disclosure are disposed on a side of the third planarization layer 703 facing towards the base substrate 100. Thus, a connection hole needs to be defined in the first planarization layer 701, the second planarization layer 702, and the third planarization layer 703, such that the first pixel circuit 201 is electrically connected to the anode 301 of the corresponding light-emitting device 300 through the connection hole. In addition, a connection hole is not defined in the planarization layer between the dummy pixel circuit 202 and the light-emitting device 300 in the display panel 000, such that the dummy pixel circuit 202 is insulated from the light-emitting device 300 through the planarization layer. Similarly, a connection hole is not defined in the planarization layer between the GOA circuit 600 and the light-emitting device 300 in the display panel 000, such that the GOA circuit 600 is insulated from the light-emitting device 300 through the planarization layer.

In the embodiments of the present disclosure, the display panel 000 further includes an encapsulation layer. The encapsulation layer is disposed on a side of a plurality of light-emitting devices 300 facing away from the base substrate 100. The encapsulation layer is capable of isolating the moisture and oxygen in the external environment, such that the moisture and oxygen in the external environment do not erode the light-emitting layer 302 in the light-emitting device 300, and the service life of the light-emitting device 300 is long.

In summary, the display panel according to the embodiments of the present disclosure includes the base substrate, the plurality of pixel circuits, the plurality of light-emitting devices, the plurality of data signal lines, and the plurality of redundant signal lines. One of the plurality of redundant signal lines includes a first lead portion connected to one of the plurality of data signal lines. The first lead portion acts as part of a fan-out lead electrically connected to the one of the plurality of data signal lines. As the plurality of redundant signal lines are disposed in the display region, the part (that is, the first lead portion) in the fan-out lead electrically connected to the one of the plurality of data signal lines is disposed in the display region, such that other part in the fan-out lead than the first lead portion occupies a decreased space in the non-display region in a case where the other part is disposed in the non-display region, and a width of a region provided with the fan-out lead in the non-display region is efficiently reduced. As such, a screen ratio of a display device equipped with the display panel is effectively improved, such that a display effect of the display device is great. In addition, the plurality of data signal lines and the plurality of redundant signal lines are disposed in the same conductive pattern, and the conductive patterns including the data signal lines and the redundant signal lines are evenly distributed in the display region. Therefore, in a case where part of the first redundant signal line in a region of one column of dummy pixel circuits acts as the part of the fan-out lead in the display region, conductive layer patterns in the display panel are evenly distributed in the display region on the premise that the part of the fan-out lead is distributed in the display region, such that a probability of color bias in the display panel is effectively reduced, and the display effect of the display panel is great.

Some embodiments of the present disclosure further provide a display device. The display device may be any product or component having a display function, such as a mobile phone, a tablet computer, a television, a display, a laptop computer, a digital photo frame, a navigator, and the like. The display device includes a power supply, and a display panel. The display panel is the display panel described above.

It should be noted that in the accompanying drawings, the dimensions of the layers and regions may be exaggerated for the clarity of illustration. Moreover, it is understandable that when an element or layer is referred to as being “on” another element or layer, it may be directly on another element, or there may be an intermediate layer. It should be further understandable that when an element or layer is referred to as being “under” another element or layer, it may be directly under another element, or there is more than one intermediate layer or element. It should be further understandable that when a layer or element is referred to as being “between two layers or two elements, it may be the only layer between the two layers or two elements, or there is more than one intermediate layer or element. Similar reference numerals indicate similar elements throughout.

In the present disclosure, the terms “first” and “second” are used for descriptive purposes only and cannot be construed as indicating or implying any relative importance. The term “a plurality of” refers to two or more, unless otherwise expressly specified.

Described above are optional embodiments of the present disclosure and are not intended to limit the present disclosure. Within the spirit and principles of the present disclosure, any variations, equivalent substitutions, improvements and the like shall be included in the protection scope of the present disclosure.

1. A display panel having a display region, the display panel comprising:
a base substrate; and
a plurality of pixel circuits arrayed on a side of the base substrate, wherein the plurality of pixel circuits comprise a plurality of first pixel circuits and a plurality of dummy pixel circuits;
a plurality of light-emitting devices on a side of the plurality of pixel circuits away from the base substrate, wherein the plurality of light-emitting devices are electrically connected to the plurality of first pixel circuits in one-to-one correspondence; and
a plurality of data signal lines and a plurality of redundant signal lines that are disposed in the display region, wherein an extension direction of the plurality of data signal lines is coincident with an extension direction of the plurality of redundant signal lines;
wherein one of the plurality of data signal lines is electrically connected to one column of the plurality of first pixel circuits, one of the plurality of redundant signal lines is disposed in a region of one column of the plurality of dummy pixel circuits, and at least some of the plurality of redundant signal lines are first redundant signal lines, wherein one of the first redundant signal lines comprises a first lead portion connected to one of the plurality of data signal lines.

2. The display panel according to claim 1, further comprising: a plurality of auxiliary signal lines in the display region, wherein an extension direction of the plurality of auxiliary signal lines is intersected with the extension direction of the plurality of redundant signal lines, one of the plurality of auxiliary signal lines is disposed in a region of one row of the plurality of pixel circuits, and at least some of the plurality of auxiliary signal lines are first auxiliary signal lines, wherein one of the first auxiliary signal lines comprises a second lead portion, wherein one end of the second lead portion is electrically connected to one of the plurality of data signal lines, and another end of the second lead portion is electrically connected to an end of the first lead portion.

3. The display panel according to claim 2, wherein one of the first redundant signal lines further comprises a redundant line body disconnected from the first lead portion, and one of the first auxiliary signal lines further comprises an auxiliary line body disconnected from the second lead portion, wherein the redundant line body is electrically connected to the auxiliary line body at an intersection between the redundant line body and the auxiliary line body.

4. The display panel according to claim 3, wherein
some of the plurality of redundant signal lines are the first redundant signal lines, and some of the plurality of redundant signal lines are second redundant signal lines, wherein the first lead portion is not disposed in the second redundant signal lines, and each of the second redundant signal lines is electrically connected to the auxiliary line body at an intersection between the each of the second redundant signal lines and the auxiliary line body; and/or
some of the plurality of auxiliary signal lines are the first auxiliary signal lines, and some of the plurality of auxiliary signal lines are second auxiliary signal lines, wherein the second lead portion is not disposed in the second auxiliary signal lines, and each of the second auxiliary signal lines is electrically connected to the redundant line body at an intersection between the each of the second auxiliary signal lines and the redundant line body.

5. The display panel according to claim 4, wherein in a case where the display panel comprises the second redundant signal lines and the second auxiliary signal lines, each of the second redundant signal lines is electrically connected to one of the second auxiliary signal lines at an intersection between the each of the second redundant signal lines and the one of the second auxiliary signal lines.

6. The display panel according to claim 4, further comprising: a first power signal line, wherein the second redundant signal lines are electrically connected to the first power signal line, and/or the second auxiliary signal lines are electrically connected to the first power signal line.

7. The display panel according to claim 6, wherein each of the plurality of light-emitting devices comprises an anode, a light-emitting layer, and a cathode layer that are stacked, wherein the anode is closer to the base substrate relative to the cathode layer, each of the plurality of first pixel circuits is electrically connected to an anode in a corresponding light-emitting devices in the plurality of light-emitting devices, and the cathode layer is electrically connected to the first power signal line.

8. The display panel according to claim 2, wherein
the display panel further has a non-display region on a periphery of the display region; and
the display panel further comprises a plurality of connection leads in the non-display region and electrically connected to the plurality of data signal lines in one-to-one correspondence, wherein each of some of the plurality of connection leads is electrically connected to a corresponding data signal line in the plurality of data signal lines through the first lead portion and the second lead portion, and each of some of the plurality of connection leads is directly electrically connected to a corresponding data signal line in the plurality of data signal lines; and the plurality of connection leads are configured to be bonded and connected to a driver assembly.

9. The display panel according to claim 2, wherein the plurality of redundant signal lines and the plurality of data signal lines are disposed in a same layer and made of a same material, and the plurality of redundant signal lines and the plurality of auxiliary signal lines are disposed in different layers.

10. The display panel according to claim 1, further comprising: a gate driver on array (GOA) circuit, wherein each of the plurality of light-emitting devices comprises an anode, a light-emitting layer, and a cathode layer that are stacked, wherein the anode is closer to the base substrate relative to the cathode layer, and an orthographic projection of the GOA circuit on the base substrate is overlapped with an orthographic projection of the anode on the base substrate.

11. The display panel according to claim 10, wherein the display region comprises a first display sub-region, a second display sub-region, and a third display sub-region; wherein
the second display sub-region is disposed between the first display sub-region and the third display sub-region, and the plurality of pixel circuits are disposed in the first display sub-region and the second display sub-region, and disposed outside the third display sub-region; at least part of the GOA circuit is disposed in the third display sub-region; and
pixel circuits in the plurality of pixel circuits disposed in the first display sub-region comprise the first pixel circuits and the dummy pixel circuits, all pixel circuits in the plurality of pixel circuits disposed in the second display sub-region are the first pixel circuits, some of the first pixel circuits in the second display sub-region are electrically connected to the plurality of light-emitting devices in the second display sub-region, and some of the first pixel circuits in the second display sub-region are electrically connected to the plurality of light-emitting devices in the third display sub-region.

12. The display panel according to claim 11, wherein in the first display sub-region, a plurality of columns of the plurality of first pixel circuits are staggered with a plurality of columns of the plurality of dummy pixel circuits.

13. The display panel according to claim 12, wherein N columns of the plurality of first pixel circuits are disposed between two adjacent columns of the plurality of dummy pixel circuits, wherein N is an integer greater than or equal to 2 and less than or equal to 6.

14. The display panel according to claim 11, wherein a density of light-emitting devices in the plurality of light-emitting devices in the first display sub-region is equal to a density of light-emitting devices in the plurality of light-emitting devices in the second display sub-region.

15. The display panel according to claim 11, wherein a plurality of columns of the plurality of first pixel circuits in the second display sub-region are correspondingly electrically connected to anodes of a plurality of columns of the plurality of light-emitting devices in the second display sub-region and in the third display sub-region.

16. The display panel according to claim 15, further comprising: a plurality of transparent connection lines in the second display sub-region and in the third display sub-region, wherein anodes of at least some of the plurality of light-emitting devices in the second display sub-region and in the third display sub-region are electrically connected to corresponding first pixel circuits through the plurality of transparent connection lines.

17. The display panel according to claim 16, wherein
the display panel further comprises a plurality of auxiliary signal lines, wherein some of the plurality of auxiliary signal lines are disposed in the second display sub-region and the third display sub-region; and
each of the plurality of transparent connection lines comprises a first transparent lead portion and a second transparent lead portion that are connected to each other, wherein an extension direction of the first transparent lead portion is coincident with an extension direction of the plurality of auxiliary signal lines, and an extension direction of the second transparent lead portion is intersected with the extension direction of the plurality of auxiliary signal lines;
wherein an orthographic projection of the first transparent lead portion on the base substrate is not coincident with an orthographic projection of each of the plurality of auxiliary signal lines on the base substrate, and an orthographic projection of the second transparent lead portion in each of at least some of the plurality of transparent connection lines is overlapped with the orthographic projection of each of the plurality of auxiliary signal lines on the base substrate.

18. The display panel according to claim 17, wherein a ratio of an overlapping area of an orthographic projection of at least one of the plurality of transparent connection lines on the base substrate and an orthographic projection of at least one of the plurality of auxiliary signal lines on the base substrate to a total area of the orthographic projection of the at least one of the plurality of transparent connection lines on the base substrate is less than or equal to 30%.

19. The display panel according to claim 16, wherein an orthographic projection of each of the anodes of at least some of the plurality of light-emitting devices in the second display sub-region and in the third display sub-region on the base substrate is overlapped with orthographic projections of at least two of the plurality of transparent connection lines on the base substrate.

20. A display device, comprising: a power supply, and a display panel electrically connected to the power supply, wherein the display panel has a display region, and comprises:
a base substrate; and
a plurality of pixel circuits arrayed on a side of the base substrate, wherein the plurality of pixel circuits comprise a plurality of first pixel circuits and a plurality of dummy pixel circuits;
a plurality of light-emitting devices on a side of the plurality of pixel circuits away from the base substrate, wherein the plurality of light-emitting devices are electrically connected to the plurality of first pixel circuits in one-to-one correspondence; and
a plurality of data signal lines and a plurality of redundant signal lines that are disposed in the display region, wherein an extension direction of the plurality of data signal lines is coincident with an extension direction of the plurality of redundant signal lines;
wherein one of the plurality of data signal lines is electrically connected to one column of the plurality of first pixel circuits, one of the plurality of redundant signal lines is disposed in a region of one column of the plurality of dummy pixel circuits, and at least some of the plurality of redundant signal lines are first redundant signal lines, wherein one of the first redundant signal lines comprises a first lead portion connected to one of the plurality of data signal lines.
